(19) United States
(12) Patent Application Publication
(10) Pub. No.: US 2025/0309746 A1
(43) Pub. Date: Oct. 2, 2025

(54) SYSTEMS, CIRCUITS, AND METHODS FOR REDUCING TRANSIENTS DURING MODE CHANGES IN A MULTI-LEVEL CONVERTER

(71) Applicant: Murata Manufacturing Co., Ltd., Kyoto (JP)

(72) Inventors: Gary Chunshien Wu, San Diego, CA (US); Robert Louis Macomber, Exeter, NH (US)

(21) Appl. No.: 19/238,257

(22) Filed: Jun. 13, 2025

Related U.S. Application Data
(63) Continuation of application No. PCT/US2023/084808, filed on Dec. 19, 2023.
(60) Provisional application No. 63/387,986, filed on Dec. 19, 2022.

(51) Int. Cl. H02M 1/00; H02M 3/07

(52) U.S. Cl. CPC H02M 1/0012; H02M 3/07

(57) ABSTRACT

The present disclosure relates to systems, circuits, and methods for reducing transients during mode changes in a multi-level converter. In one embodiment, the multi-level converter is capable of operations in a charge pump mode by open loop control and a regulation mode by closed-loop control. A control circuit for controlling a pulse-width modulation (PWM) signal for the multi-level converter, includes a compensation signal generation circuit configured to generate a compensation signal, and a PWM circuit configured to generate a PWM signal with a target duty cycle based on the compensation signal when the multi-level converter operates in the charge pump mode. The PWM signal with the target duty cycle is used for controlling the multi-level converter in a mode change from the charge pump mode to the regulation mode.

### CROSS-REFERENCE TO RELATED APPLICATION

The present application is a continuation of International Patent Application No. PCT/US2023/084808 filed Dec. 19, 2023, and International Patent Application No. PCT/US2023/084808 claims the benefit of and priority to U.S. Provisional Application No. 63/387,986, filed on Dec. 19, 2022, the entire contents of which are incorporated herein by reference in their entirety.

### TECHNICAL FIELD

The present disclosure relates to switched capacitor circuit multi-level step-down converters, and more particularly, to systems, circuits, and methods for reducing transients during mode changes in a multi-level converter.

### BACKGROUND

Many electronic products, particularly mobile computing and/or communication products and components (e.g., notebook computers, ultra-book computers, tablet devices, LCD and LED displays), require multiple voltage levels. For example, power amplifiers for radio frequency transmitters may require relatively high voltages (e.g., 12 volts (V) or more), and logic circuitry may require a low voltage level (e.g., 1-2 V). Some other circuits may require an intermediate voltage level (e.g., 5-10 V). Various configurations of switched capacitor power conversion circuits, sometimes also known as “charge pumps,” provide voltage conversion (i.e., step up, step down, or bidirectional) between a high side voltage and a low side voltage through controlled transfers of charge between capacitors in the circuit.

### SUMMARY

Embodiments of the present disclosure may provide systems, circuits, and methods for reducing transients during mode changes in a multi-level converter. In one embodiment, the multi-level converter is capable of operations in a charge pump mode by open loop control and a regulation mode by closed-loop control. A control circuit for controlling a pulse-width modulation (PWM) signal for the multi-level converter, includes a compensation signal generation circuit configured to generate a compensation signal, and a PWM circuit configured to generate a PWM signal with a target duty cycle based on the compensation signal when the multi-level converter operates in the charge pump mode. The PWM signal with the target duty cycle is used for controlling the multi-level converter in a mode change from the charge pump mode to the regulation mode.

In another embodiment, a method for controlling a multi-level converter, includes determining a duty cycle of a pulse-width modulation (PWM) signal, the PWM signal being configured for controlling the multi-level converter. The method also includes determining at least one of: whether the duty cycle of the PWM signal is moved down, moved up, or not changing, or whether the duty cycle of the PWM signal is less than a target duty cycle or greater than the target duty cycle. The method further includes responsive to a determination that the duty cycle of the PWM signal is moved down or a determination that the duty cycle of the PWM signal is less than the target duty cycle, increasing a parameter to increase the duty cycle of the PWM signal. The method also includes responsive to a determination that the duty cycle of the PWM signal is moved up or a determination that the duty cycle of the PWM signal is greater than the target duty cycle, decreasing the parameter to decrease the duty cycle of the PWM signal.

In another embodiment, a system for reducing transients during changes of power conversion modes, includes a multi-level converter configured to operate in a charge pump mode or a regulation mode, to provide an output voltage signal. The system also includes a control circuit configured to control the multi-level converter to operate with a duty cycle of 50% in the charge pump mode by open-loop control, or to operate with a variable duty cycle in the regulation mode by closed-loop control; and generate a pulse-width modulation (PWM) signal with a target duty cycle when the multi-level converter operates in the charge pump mode. The PWM signal with the target duty cycle being used for controlling the multi-level converter in a mode change from the charge pump mode to the regulation mode.

Yet in another embodiment, a system for reducing transients during mode changes in a switched capacitor circuit multi-level step-down converter is disclosed. The system comprises a switched capacitor-based step-down converter, and a control circuit to control the switched capacitor-based step-down converter. The control circuit is capable of open-loop and closed-loop control of the switched capacitor-based step-down converter. The control circuit during open-loop control is configured to control a duty cycle of one or more control signals to the switched capacitor-based step-down converter at about, for example, 33.3% or 66.6%, using feedback from an output of the switched capacitor-based step-down converter.

It is to be understood that the foregoing general description and the following detailed description are exemplary and explanatory only, and are not restrictive of the invention, as claimed.

### BRIEF DESCRIPTION OF THE DRAWINGS

FIG. 1 is a circuit diagram of an example switched capacitor circuit multi-level step-down converter, consistent with disclosed embodiments.

FIG. 2 is a block diagram illustrating example aspects of operating a switched capacitor circuit multi-level step-down converter in open-loop mode, consistent with disclosed embodiments.

FIG. 3A is a block diagram illustrating example aspects of operating a switched capacitor circuit multi-level step-down converter in closed-loop voltage mode, consistent with disclosed embodiments.

FIG. 3B is a circuit diagram illustrating example aspects of a controller for a switched capacitor circuit multi-level step-down converter operating in closed-loop voltage mode, consistent with disclosed embodiments.

FIG. 4A is a block diagram illustrating example aspects of operating a switched capacitor circuit multi-level step-down converter in closed-loop current mode, consistent with disclosed embodiments.

FIG. 4B is a circuit diagram illustrating example aspects of a controller for a switched capacitor circuit multi-level step-down converter operating in closed-loop current mode, consistent with disclosed embodiments.

FIGS. 5A-5B are block diagrams illustrating example aspects of changing operating mode in a switched capacitor circuit multi-level step-down converter, consistent with disclosed embodiments.

FIG. 6 is a state flow diagram illustrating example aspects of controlling a switched capacitor circuit multi-level step-down converter, consistent with disclosed embodiments.

### DETAILED DESCRIPTION

The following disclosure provides many different exemplary embodiments, or examples, for implementing different features of the provided subject matter. Specific simplified examples of components and arrangements are described below to explain the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Many electronic products, particularly mobile computing and/or communication products and components (e.g., notebook computers, ultra-book computers, tablet devices, LCD and LED displays), require multiple voltage levels. For example, power amplifiers for radio frequency transmitters may require relatively high voltages (e.g., 12 volts (V) or more), and logic circuitry may require a low voltage level (e.g., 1-2 V). Some other circuits may require an intermediate voltage level (e.g., 5-10 V). Power converters are often used to generate a lower or higher voltage from a common power source, such as a battery, to meet the power requirements of different components in electronic products.

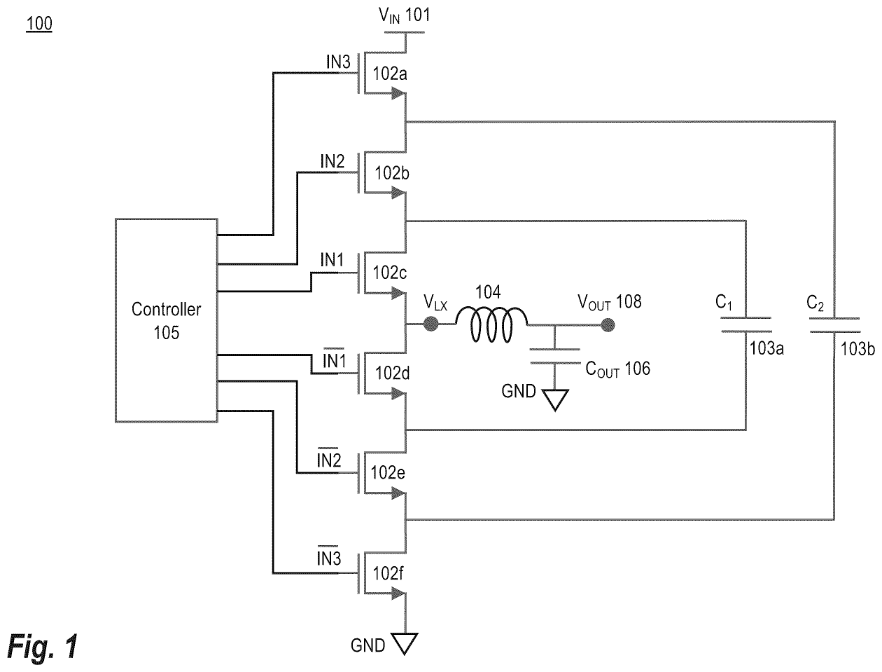

FIG. 1 is a circuit diagram 100 of an example switched capacitor circuit multi-level step-down conversion circuit, consistent with disclosed embodiments. Various embodiments of switched capacitor power conversion circuits provide voltage conversion, e.g., step down conversion between a high side voltage (e.g., input voltage V_{IN} 101) and a low side voltage (e.g., output voltage V_{OUT} 108) through controlled transfers of charge between fly capacitors (e.g., 103a-b) in the circuit. Charge pumps step down an input voltage by storing a fraction of the input voltage across each fly capacitor (e.g., 103a-b). Switches (e.g., 102a-f) coupled to both terminals of each fly capacitor are typically used to perform the charge transfer and configure the charge pump to provide a desired voltage conversion ratio. Control of the charge transfer between the fly capacitors 103a-b generally makes use of circuit elements that act as “switches,” for example, diodes or FET transistors. Switched capacitor circuit multi-level step-down conversion circuit 100 may include an inductor 104 configured so that circuit 100 operates as a buck converter. It is to be understood that the principles of the present disclosure may be applied to any other type of step-down DC-to-DC converter, such as a boost, buck-boost, or Ćuk converter. Lastly, switched capacitor circuit multi-level step-down conversion circuit 100 may include a controller 105 to control operation of switches 102a-f. For example, controller 105 may provide control signals, e.g., IN1, IN2, and IN3, to control the timing of the opening and closing of switches 102a-f to control the charge transfer between the fly capacitors 103a-b. Thus, controller 105 may control the output voltage V_{OUT} 108 and the voltage step-down conversion ratio (V_{OUT} 108/V_{IN} 101).

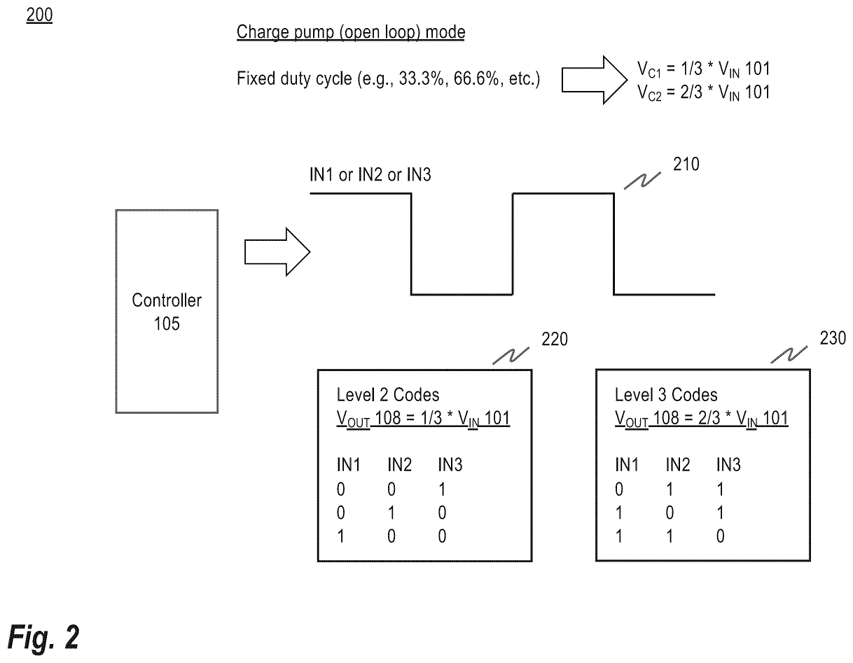

FIG. 2 is a block diagram 200 illustrating example aspects of operating a switched capacitor circuit multi-level step-down converter in open-loop mode, consistent with disclosed embodiments. In various embodiments, controller 105 of switched capacitor circuit multi-level step-down conversion circuit 100 may be operated in an open-loop mode (sometimes referred to as a “charge pump” mode) or a closed-loop mode (sometimes referred to as a “regulation” mode). For example, in open-loop mode, the controller 105 may not utilize feedback from the output voltage V_{OUT} 108 to determine the timing of the opening and closing of switches 102a-f to control charge transfer between the fly capacitors 103a-b. Instead, controller 105 may provide control signals IN1, IN2, and IN3 to close and open switches 102a-f that have a fixed duty cycle (on-off ratio), such as 33.3% or 66.6% (see, e.g., FIG. 2, element 210). For example, with reference to the four-level step-down converter shown in FIG. 1, control signals IN1, IN2, and IN3 may be provided with a 33.3% duty cycle (ON) each (and 120° out of phase with each other) to obtain an output voltage V_{OUT} 108 of 1/3*V_{IN} 101, or with a 33.3% duty cycle (OFF) (i.e., a 66.6% duty cycle (ON)) each (and 120° out of phase with each other) to obtain an output voltage V_{OUT} 108 of 2/3* V_{IN} 101. In such scenarios, the voltage V_{LX} indicated in FIG. 1 would experience a 50% duty cycle, representing a duty cycle for the switch state transition of 50%. Persons of ordinary skill in the art would understand how to set the duty cycles and phases of the control signals for an N-level converter to achieve each of the N levels in open-loop mode.

With reference to FIG. 1, in some embodiments of the switched capacitor circuit multi-level step-down conversion circuit 100, the capacitors 103a-b and output capacitance C_{OUT} 106 may be sized such that when controller 105 provides control signals IN1, IN2, and IN3 with a fixed duty cycle, the voltages V_{C1} and V_{C2} across fly capacitances 103a and 103b respectively during operation are about 1/3* V_{IN} 101 and 2/3* V_{IN} 101 respectively.

Moreover, in open-loop mode, the controller 105 may control the phase of the control signals IN1, IN2, and IN3 such that the output voltage V_{OUT} 108 is about 1/3* V_{IN} 101 or 2/3* V_{IN} 101. For example, as shown in FIG. 2, table 220, to achieve an output voltage V_{OUT} 108 of about 1/3* V_{IN} 101 (level 2 of a 4-level converter with output voltages of 0V, 1/3* V_{IN} 101, 2/3* V_{IN} 101, and V_{IN} 101), the controller 105 in open-loop mode may close one of switch 102a, 102b, or 102c (i.e., the switches coupled to one terminal of the fly capacitors 103a-b) at a time, and at the same time open a corresponding switch 102d, 102e, or 102f (i.e., the switches coupled to the other terminal of the fly capacitors 103a-b).

As an example, the controller 105 may assert IN1 and IN2 low (a logical ‘0’) while asserting IN3 high (a logical ‘1’). When the controller asserts this {IN1 IN2 IN3 } code of {0 0 1}, switch 102a may be closed, while switches 102b and 102c may be open. At the other terminal of the fly capacitators 103a and 103b, switch 102f may be open, while switches 102d and 102e may be closed. In this configuration, the output voltage V_{OUT} 108 may be about 1/3* V_{IN} 101 (i.e., conversion ratio of 1/3 (level 2)).

Similarly, the controller 105 may assert IN1 and IN3 low (a logical ‘0’) while asserting IN2 high (a logical ‘1’). When the controller asserts this {IN1 IN2 IN3 } code of {0 1 0}, switch 102b may be closed, while switches 102a and 102c may be open. At the other terminal of the fly capacitators 103a and 103b, switch 102e may be open, while switches 102d and 102f may be closed. In this configuration, the output voltage V_{OUT} 108 may be about 1/3* V_{IN} 101 (i.e., conversion ratio of 1/3 (level 2)).

Similarly, the controller 105 may assert IN2 and IN3 low (a logical ‘0’) while asserting IN1 high (a logical ‘1’). When the controller asserts this {IN1 IN2 IN3 } code of {1 00}, switch 102c may be closed, while switches 102a and 102b may be open. At the other terminal of the fly capacitators 103a and 103b, switch 102d may be open, while switches 102e and 102f may be closed. In this configuration, the output voltage V_{OUT} 108 may be about 1/3* V_{IN} 101 (i.e., conversion ratio of 1/3 (level 2)). In some embodiments, the controller 105 may successively cycle through the level 2 codes {00 1}, {0 10}, and {1 00} with a 33% duty cycle each to achieve the output voltage V_{OUT} 108 of about 1/3 * V_{IN} 101 (i.e., conversion ratio of 1/3 (level 2)).

Further, in open-loop mode, the controller 105 may control the phase of the control signals IN1, IN2, and IN3 such that the output voltage V_{OUT} 108 is about 2/3* V_{IN} 101. For example, as shown in FIG. 2, table 230, to achieve an output voltage V_{OUT} 108 of about 2/3* V_{IN} 101 (level 3 of a 4-level converter with output voltages of 0V, 1/3* V_{IN} 101, 2/3* V_{IN} 101, and V_{IN} 101), the controller 105 in open-loop mode may close two of switches 102a, 102b, or 102c (i.e., the switches coupled to one terminal of the fly capacitors 103a-b) at a time, and at the same time open two corresponding switches 102d, 102e, or 102f (i.e., the switches coupled to the other terminal of the fly capacitors 103a-b).

As an example, the controller 105 may assert IN1 low (a logical ‘0’) while asserting IN2 and IN3 high (a logical ‘1’). When the controller asserts this {IN1 IN2 IN3 } code of {0 1 1}, switch 102c may be open, while switches 102a and 102b may be closed. At the other terminal of the fly capacitators 103a and 103b, switch 102d may be closed, while switches 102e and 102f may be open. In this configuration, the output voltage V_{OUT} 108 may be about 2/3* V_{IN} 101 (i.e., conversion ratio of 2/3 (level 3)).

Similarly, the controller 105 may assert IN2 low (a logical ‘0’) while asserting IN1 and IN3 high (a logical ‘1’). When the controller asserts this {IN1 IN2 IN3 } code of {1 0 1}, switch 102b may be open, while switches 102a and 102c may be closed. At the other terminal of the fly capacitators 103a and 103b, switch 102e may be closed, while switches 102d and 102f may be open. In this configuration, the output voltage V_{OUT} 108 may be about 2/3* V_{IN} 101 (i.e., conversion ratio of 2/3 (level 3)).

Similarly, the controller 105 may assert IN3 low (a logical ‘0’) while asserting IN1 and IN2 high (a logical ‘1’). When the controller asserts this {IN1 IN2 IN3 } code of {1 1 0}, switch 102a may be open, while switches 102b and 102c may be closed. At the other terminal of the fly capacitators 103a and 103b, switch 102f may be closed, while switches 102d and 102e may be open. In this configuration, the output voltage V_{OUT} 108 may be about 2/3* V_{IN} 101 (i.e., conversion ratio of 2/3 (level 3)). In some embodiments, the controller 105 may successively cycle through the level 3 codes {0 1 1}, {1 0 1}, and {1 1 0} with a 33% duty cycle (OFF) (i.e., a 66.6% duty cycle (ON)) each to achieve the output voltage V_{OUT} 108 of about 2/3* V_{IN} 101 (i.e., conversion ratio of 2/3 (level 3)).

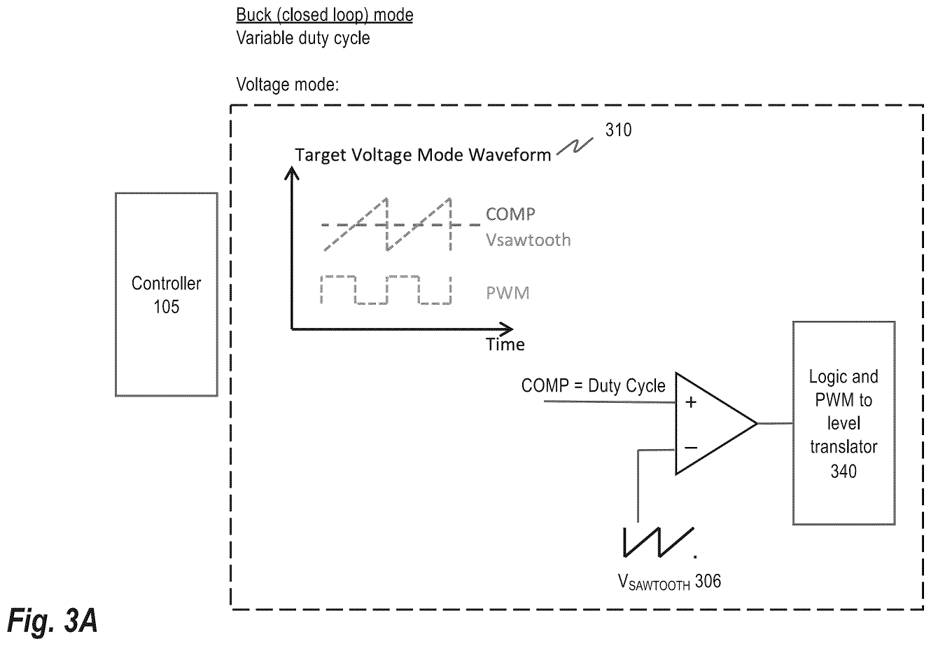

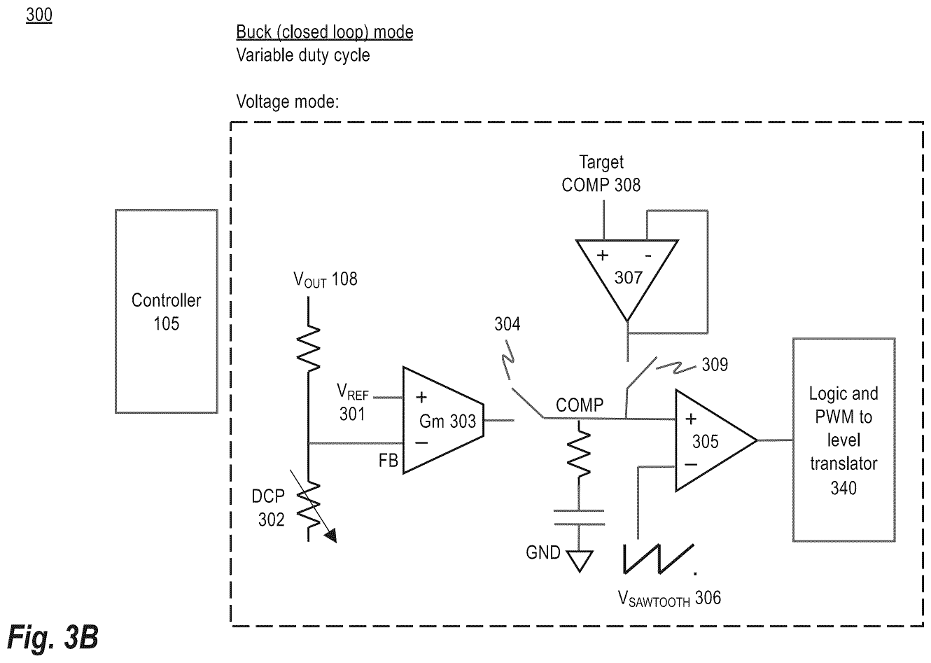

FIG. 3A is a block diagram illustrating example aspects of operating a switched capacitor circuit multi-level step-down converter in closed-loop voltage mode, consistent with disclosed embodiments. In various embodiments, controller 105 of switched capacitor circuit multi-level step-down conversion circuit 100 may be operated in an open-loop mode (sometimes referred to as a “charge pump” mode) or a closed-loop mode (sometimes referred to as a “regulation” mode). For example, in closed-loop mode, the controller 105 may utilize feedback from the output voltage V_{OUT} 108 to determine the timing of the opening and closing of switches 102a-f to control charge transfer between the fly capacitors 103a-b. Accordingly, in some embodiments, controller 105 may provide control signals IN1, IN2, and IN3 with variable duty cycle (on-off ratio) to close and open switches 102a-f, to maintain a constant output voltage V_{OUT} 108.

With reference to FIG. 3A, in some embodiments of the switched capacitor circuit multi-level step-down conversion circuit 100, the controller 105 operating in closed-loop voltage mode may utilize a pulse width modulation technique to vary the duty cycle of control signals IN1, IN2, and IN3 to close and open switches 102a-f. For example, as shown in FIG. 3A (see, e.g., element 310) controller 105 may include a comparator that compares a voltage sawtooth waveform 306 against a COMP signal (representing a target output voltage) to modulate the width of a gencrated pulse provided to logic and PWM to level translator 340, which may provide control signals to generate an output voltage V_{OUT} 108 that is maintained at a constant voltage. When operating in such a closed-loop voltage mode, the switched capacitor circuit multi-level step-down conversion circuit 100 may generate a range of output voltage Vo_{OUT} 108 between about 0V and about V_{IN} 101.

FIG. 3B is a circuit diagram 300 illustrating example aspects of a controller for a switched capacitor circuit multi-level step-down converter operating in closed-loop voltage mode, consistent with disclosed embodiments. In some embodiments, controller 105 operating in closed-loop voltage mode may include a comparator 305 (i.e., a PWM circuit) to modulate the width of a generated pulse (e.g., a PWM signal) provided to logic and PWM to level translator 340, which may provide control signals to generate an output voltage V_{OUT} 108 that is maintained at a constant voltage. Comparator 305 may compare a voltage sawtooth waveform 306 against a COMP signal to modulate the width of the generated pulse. The COMP signal may be manipulated/controlled using multiple techniques, as discussed further below.

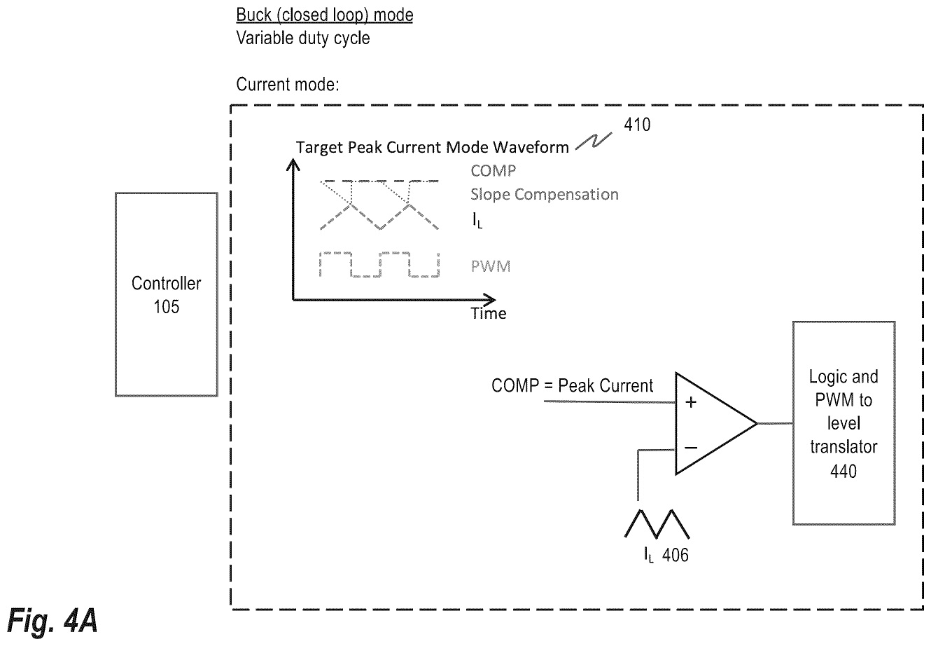

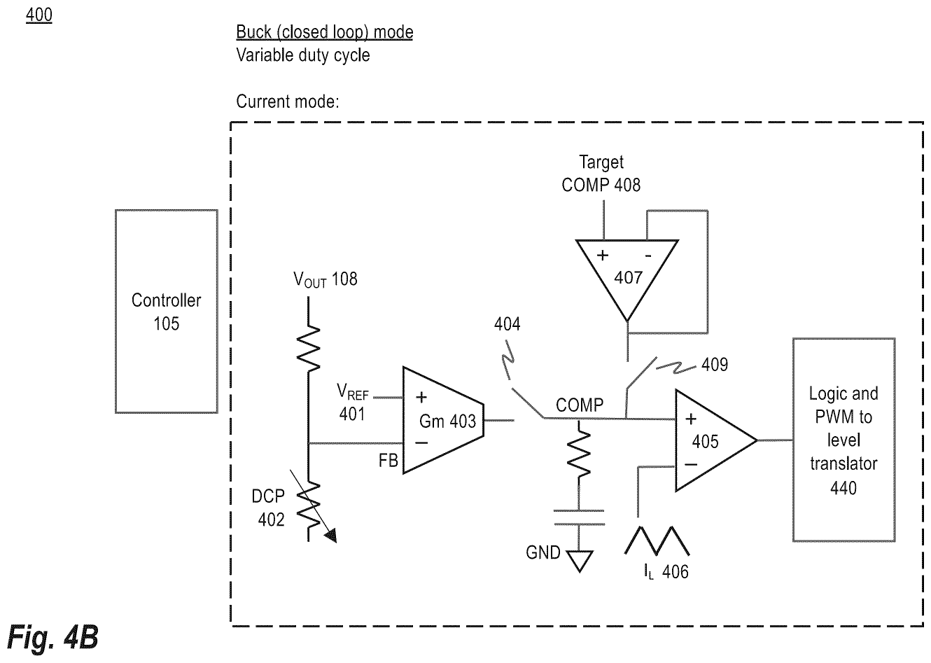

FIG. 4A is a block diagram illustrating example aspects of operating a switched capacitor circuit multi-level step-down converter in closed-loop current mode, consistent with disclosed embodiments. As stated above, in various embodiments, controller 105 of switched capacitor circuit multi-level step-down conversion circuit 100 may be operated in an open-loop mode (sometimes referred to as a “charge pump” mode) or a closed-loop mode (sometimes referred to as a “regulation” mode). For example, in closed-loop mode, the controller 105 may utilize feedback from the output voltage V_{OUT} 108, as well as an output current, to determine the timing of the opening and closing of switches 102a-f to control charge transfer between the fly capacitors 103a-b. Accordingly, in some embodiments, controller 105 may provide control signals IN1, IN2, and IN3 with variable duty cycle (on-off ratio) to close and open switches 102a-f, to maintain a constant output voltage V_{OUT} 108.

With reference to FIG. 4A, in some embodiments of the switched capacitor circuit multi-level step-down conversion circuit 100, the controller 105 operating in closed-loop current mode may utilize a pulse width modulation technique to vary the duty cycle of control signals IN1, IN2, and IN3 to close and open switches 102a-f. For example, as shown in FIG. 4A (see, e.g., element 410) controller 105 may include a comparator that compares a current I_{L} sawtooth waveform 406 representative of the inductor 104 against a COMP signal to modulate the width of a generated pulse provided to logic and PWM to level translator 440, which may provide control signals to maintain a constant output voltage V_{OUT} 108. When operating in such a closed-loop current mode, the switched capacitor circuit multi-level step-down conversion circuit 100 may generate a range of output voltage V_{OUT} 108 between about 0V and about V_{IN} 101.

FIG. 4B is a circuit diagram 400 illustrating example aspects of a controller for a switched capacitor circuit multi-level step-down converter operating in closed-loop current mode, consistent with disclosed embodiments. In some embodiments, controller 105 operating in closed-loop current mode may include a comparator 405 (i.e., a PWM modulator) to modulate the width of a generated pulse (e.g., a PWM signal) provided to logic and PWM to level translator 440, which may provide control signals to generate a constant output voltage V_{OUT} 108. Comparator 405 may compare a current I_{L}, sawtooth (or triangle) waveform 406 against a COMP signal to modulate the width of the generated pulse. The COMP signal may be controlled using multiple techniques, as discussed further below.

As discussed above with reference to FIG. 2, FIGS. 3A-B and FIGS. 4A-B, in a switched capacitor circuit multi-level step-down converter, the input voltage V_{IN} 101 can be stepped down using either a “regulation” mode in closed-loop to regulate the output voltage V_{OUT} 108 to a desired level using either voltage mode or current mode control, or the input voltage V_{IN} 101 can be stepped down using a “charge pump” mode in open-loop. Depending on the particulars of the application, it may be sometimes desirable to operate the switched capacitor circuit multi-level step-down converter in “charge pump” mode, and sometimes in “regulation” mode, and sometimes to transition between the two modes of operation. The inventors here have recognized, however, that the transition from one mode of operation to another, e.g., from “charge pump” mode to “regulation” mode, may cause transients in the output voltage V_{OUT} 108, which can take an undesirably long time to recover from depending on the system bandwidth, and may also cause an over-voltage fault to occur with respect to the output voltage V_{OUT} 108.

In particular with respect to FIG. 2, the controller 105 operating in open-loop “charge pump” mode may not utilize feedback from the output voltage V_{OUT} 108 to determine the timing of the opening and closing of switches 102a-f to control charge transfer between the fly capacitors 103a-b. Accordingly, the controller 105 operating in “charge pump” mode may not utilize any pulse width modulation technique, such as those shown in FIGS. 3A-B and FIGS. 4A-B, to vary the duty cycle of control signals IN1, IN2, and IN3 to close and open switches 102a-f. Nevertheless, for controller 105 to quickly transition from “charge pump” mode to “regulation” mode (closed-loop current or voltage mode), the pulse width modulation circuitry may need to be operating even if it is not being used in open-loop “charge pump” mode. Accordingly, in some embodiments, the pulse width modulation circuitry may continue to be operated even when it is not being used in open-loop “charge pump” mode to vary the duty cycle of control signals IN1, IN2, and IN3.

During such operation in open-loop “charge pump” mode, the pulse width modulation circuitry may undesirably be pre-conditioned to provide an extreme COMP signal to modulate the width of the generated pulse. This is because during open-loop “charge pump” mode operation, the output voltage V_{OUT} 108 may decrease with increasing load current. For example, with respect to the pulse width modulation circuitry illustrated in FIG. 3B, such a decrease in the output voltage V_{OUT} 108 may cause the transconductance amplifier Gm 303 upon comparing the decreased output voltage V_{OUT} 108 with a reference voltage V_{REF} 301 to output a COMP signal to compensate for the decrease in the output voltage V_{OUT} 108. For example, Gm 303 may output a current signal proportional to the difference in the voltages input to it, which current signal may be converted into a voltage signal using an output resistor and capacitor. But since the controller 105 is operating in open-loop “charge pump” mode, the COMP signal may not be utilized to vary the duty cycle of control signals IN1, IN2, and IN3 (see FIG. 1), and thus the output voltage V_{OUT} 108 may remain decreased despite the COMP signal attempting to compensate for decreased output voltage V_{OUT} 108. This may lead to the COMP signal railing high in open-loop “charge pump” mode. Similarly, for example, with respect to the pulse width modulation circuitry illustrated in FIG. 4B, such a decrease in the output voltage V_{OUT} 108 may cause the transconductance amplifier Gm 403 upon comparing the decreased output voltage V_{OUT} 108 with a reference voltage V_{REF} 401 to output a COMP signal to compensate for the decrease in the output voltage V_{OUT} 108. For example, Gm 403 may output a current signal proportional to the difference in the voltages input to it, which current signal may be converted into a voltage signal using an output resistor and capacitor. But since the controller 105 is operating in open-loop “charge pump” mode, the COMP signal may not be utilized to vary the duty cycle of control signals IN1, IN2, and IN3 (see FIG. 1), and thus the output voltage V_{OUT} 108 may remain decreased despite the COMP signal attempting to compensate for decreased output voltage V_{OUT} 108. This may lead to the COMP signal railing high in open-loop “charge pump” mode.

Because the COMP signal has been compensated to the maximum possible extent during open-loop “charge pump” mode operation, e.g., the COMP signal has been railed high, the effect of operating the pulse width modulation circuitry even when it is not being used in open-loop “charge pump” mode may be to bias or pre-condition the pulse width modulation circuitry to set high duty cycle values for control signals IN1, IN2, and IN3 when the switched capacitor circuit multi-level step-down converter transitions from “charge pump” mode to “regulation” mode. In various embodiments, this condition may bias or pre-conditioning the pulse width modulation circuitry to set high duty cycle states in “regulation” closed-loop voltage mode control or high current states in a “regulation” closed-loop peak or average current mode control when transitioning from open-loop “charge pump” mode. This bias or pre-conditioning may cause transients in the output voltage V_{OUT} 108, which can take an undesirably long time to recover from depending on the system bandwidth, and may also cause an over-voltage fault to occur with respect to the output voltage V_{OUT} 108.

Embodiments of the present disclosure may mitigate and/or prevent the pulse width modulation circuitry from driving the COMP signal to extreme or undesirable levels during open-loop “charge pump” mode operation. For example, during open-loop “charge pump” mode operation, the controller 105 may set the COMP voltage close to the voltage that it needs to be at when the switched capacitor circuit multi-level step-down converter transitions from “charge pump” mode to “regulation” mode. For example, for transitioning from “charge pump” mode to “regulation” closed-loop voltage mode, the controller 105 may set the COMP voltage so that the duty cycle of the V_{LX} signal is about 50%. As another example, for transitioning from “charge pump” mode to “regulation” closed-loop peak or average current mode, the controller 105 may set the COMP voltage so that the duty cycle of the V_{LX} signal is less than about 50%, e.g., preferably to have a linear range of COMP voltage versus duty cycle and slope compensation less than one.

With reference to FIG. 3B and FIG. 4B, to accomplish the desired COMP voltage, the controller 105 may adjust the resistance of the feedback resistance divider using a digitally controlled potentiometer (DCP) 302/402 (i.e., an adjustable resistor whose resistance is controlled by a digital code, e.g., a series of bits) so that the feedback voltage V_{FB} at the node FB of Gm 303/403 is at or near the reference voltage V_{REF} 301/401, or so that the desired target COMP voltage is achieved. Once near the desired target COMP, adjacent DCP codes may be generated to maintain the desired target COMP voltage and duty cycle (e.g., 33.3%). Such a scheme may be advantageously employed in example embodiments using a field-programmable gate array. Alternatively, the controller 105 may adjust the reference voltage V_{REF} 301/401 so that the desired target COMP voltage is achieved. In some alternatives, a digitally controlled V_{REF} 301/401 can be compared directly against the output voltage V_{OUT} 108 without use of a resistive divider circuit. Such schemes may be advantageously employed in example integrated circuit embodiments.

In yet another alternative, the controller 105 may include an analog circuit 307/407 that compares a target COMP voltage 308/408 to the current COMP signal and adjusts the current COMP signal to the desired target level. In some embodiments, the analog circuit 307/407 may be coupled to the COMP terminal, e.g., by closing switch 309/409, while other components of the pulse width modulation circuitry may be disconnected, e.g., by opening switch 304/404. For example, for transitioning from “charge pump” mode to “regulation” closed-loop voltage mode, the controller 105 may set the COMP voltage to the mid-point of the voltage sawtooth waveform 306. Similarly, for transitioning from “charge pump” mode to “regulation” closed-loop current mode, the controller 105 may measure the load current and determine the target COMP voltage accordingly, which may then be provided as target COMP 408. It is to be understood that any combination of the above-discussed techniques may be used to accomplish the desired target COMP voltage during open-loop “charge pump” mode operation.

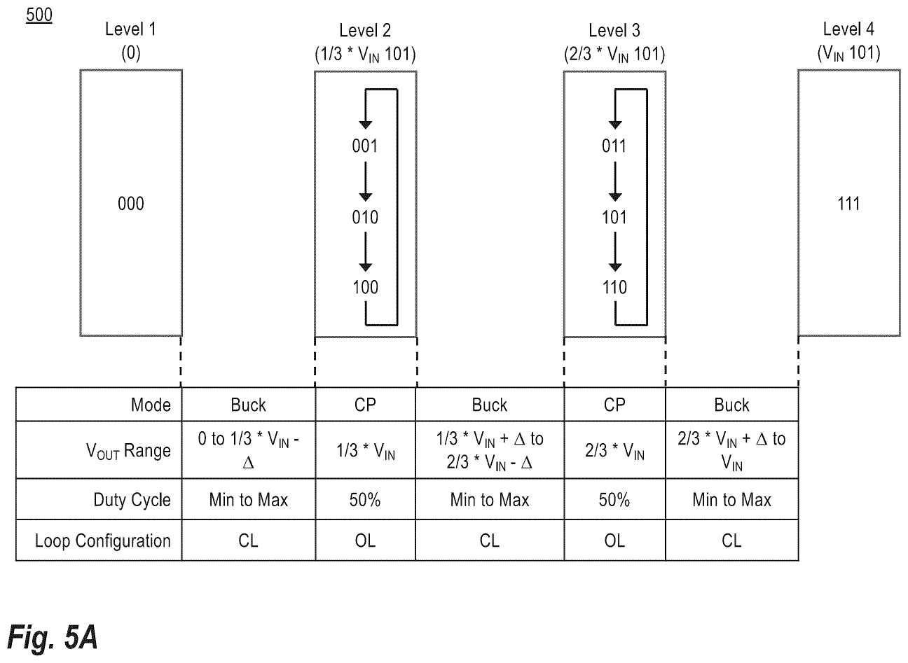

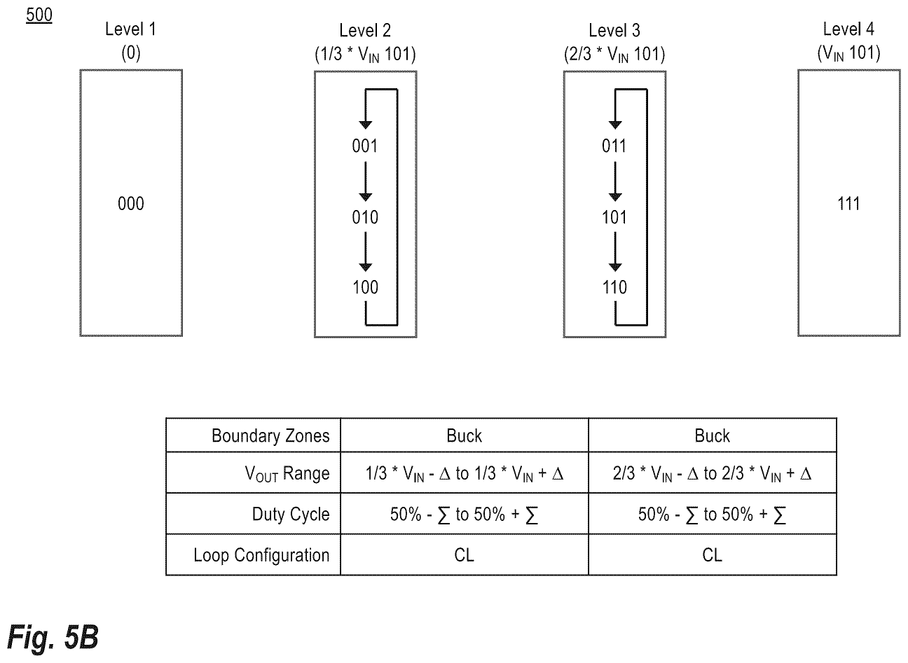

FIGS. 5A-5B are block diagrams 500 illustrating example aspects of changing operating mode in a switched capacitor circuit multi-level step-down converter, consistent with disclosed embodiments. With reference to FIG. 5A, in some embodiments, controller 105 of an exemplary four-level switched capacitor circuit step-down conversion circuit 100 may be operated in an open-loop “charge pump” mode or a closed-loop mode (voltage or current control) “regulation” mode. As shown in FIG. 5A, four-level switched capacitor circuit step-down conversion circuit 100 may be able to accept input voltage V_{IN} 101 and provide four fixed output voltage V_{OUT} 108 levels using the open-loop “charge pump” mode, e.g., 0 (level 1), 1/3* V_{IN} 101 (level 2), 2/3* V_{IN} 101 (level 3), and V_{IN} 101 (level 4). In particular, when providing level 2 or level 3 output voltage V_{OUT} 108, the switched capacitor circuit step-down conversion circuit 100 may be operating in open-loop (OL) “charge pump” mode using a 33.3% or 66.6% fixed duty cycle for control signals IN1, IN2, and IN3. As described above with reference to FIG. 2, in some embodiments, the controller 105 may successively cycle through the level 2 codes {00 1}, {0 1 0}, and {1 00} to achieve the output voltage V_{OUT} 108 of about 1/3* V_{IN} 101 (i.e., conversion ratio of 1/3 (level 2)). Similarly, in some embodiments, the controller 105 may successively cycle through the level 3 codes {0 1 1}, {10 1}, and {1 1 0} to achieve the output voltage V_{OUT} 108 of about 2/3* V_{IN} 101 (i.e., conversion ratio of 2/3 (level 3)).

Further, as shown in FIG. 5A, the switched capacitor circuit step-down conversion circuit 100 may provide variable output voltage V_{OUT} 108 in between the fixed levels using the closed-loop mode (voltage or current control) “regulation” mode. For example, in between the 0 (level 1) and 1/3* V_{IN} 101 (level 2) levels, the switched capacitor circuit step-down conversion circuit 100 may operate in closed-loop “regulation” mode, using a varying duty cycle (min to max) for control signals IN1, IN2, and IN3 to continuously control the output voltage V_{OUT} 108 between 0 and 1/3* V_{IN} 101−Δ, where Δ is a voltage boundary zone window of V_{OUT} 108. Similarly, in between the 1/3* V_{IN} 101 (level 2) and 2/3* V_{IN} 101 (level 3) levels, the switched capacitor circuit step-down conversion circuit 100 may operate in closed-loop “regulation” mode, using a varying duty cycle (min to max) for control signals IN1, IN2, and IN3 to continuously control the output voltage V_{OUT} 108 between 1/3* V_{IN} 101+Δ and 1/3* V_{IN} 101−Δ, where is a voltage boundary zone window of V_{OUT} 108. Further, in between the 2/3* V_{IN} 101 (level 3) and V_{IN} 101 (level 4) levels, the switched capacitor circuit step-down conversion circuit 100 may operate in closed-loop “regulation” mode, using a varying duty cycle (min to max) for control signals IN1, IN2, and IN3 to continuously control the output voltage V_{OUT} 108 between 2/3* V_{IN} 101+Δ and V_{IN} 101.

With reference to FIG. 5B, during open-loop “charge pump” mode operation at level 2 (1/3* V_{IN} 101) or level 3 (2/3* V_{IN} 101), the controller 105 may set the COMP voltage close to the voltage that it needs to be at when the switched capacitor circuit multi-level step-down converter transitions from “charge pump” mode to “regulation” mode. For example, for transitioning from “charge pump” mode to “regulation” closed-loop voltage mode at around level 2(1/3* V_{IN} 101±Δ) or level 3 (2/3* V_{IN} 101±Δ), the controller 105 may set the COMP voltage so that the duty cycle of a switch state transition, e.g., a duty cycle of the V_{LX} signal, is about 50% (e.g., 50%±Σ, where Σ is a boundary zone window of an equivalent duty cycle). As another example, for transitioning from “charge pump” mode to “regulation” closed-loop peak or average current mode at around level 2 (1/3* V_{IN} 101±Δ) or level 3 (2/3* V_{IN} 101±Δ), the controller 105 may set the COMP voltage so that the duty cycle of the V_{LX} signal is about is less than about 50% (e.g., 50%−Σ, where Σ is a boundary zone window of an equivalent duty cycle), e.g., preferably to have a linear range of COMP voltage versus duty cycle and slope compensation less than one.

As explained above with reference to FIG. 3B and FIG. 4B, to accomplish the desired COMP voltage, the controller 105 may adjust the resistance of the feedback resistance divider using a digitally controlled potentiometer DCP 302/402 so that the feedback voltage V_{FB} at the node FB of Gm 303/403 is at or near the reference voltage V_{REF} 301/401, or so that the desired target COMP voltage is achieved. Once near the desired target COMP, adjacent DCP codes may be toggled to maintain the desired target COMP voltage and V_{LX} signal duty cycle (e.g., 50%). Such a scheme may be advantageously employed in example embodiments using a field-programmable gate array. Alternatively, a digitally controlled V_{REF} 301/401 can also be used with a fixed resistive divider. As another alternative, a digitally controlled V_{REF} 301/401 can be compared directly against the output voltage V_{OUT} 108 without use of a resistive divider circuit. Such schemes may be advantageously employed in example integrated circuit embodiments.

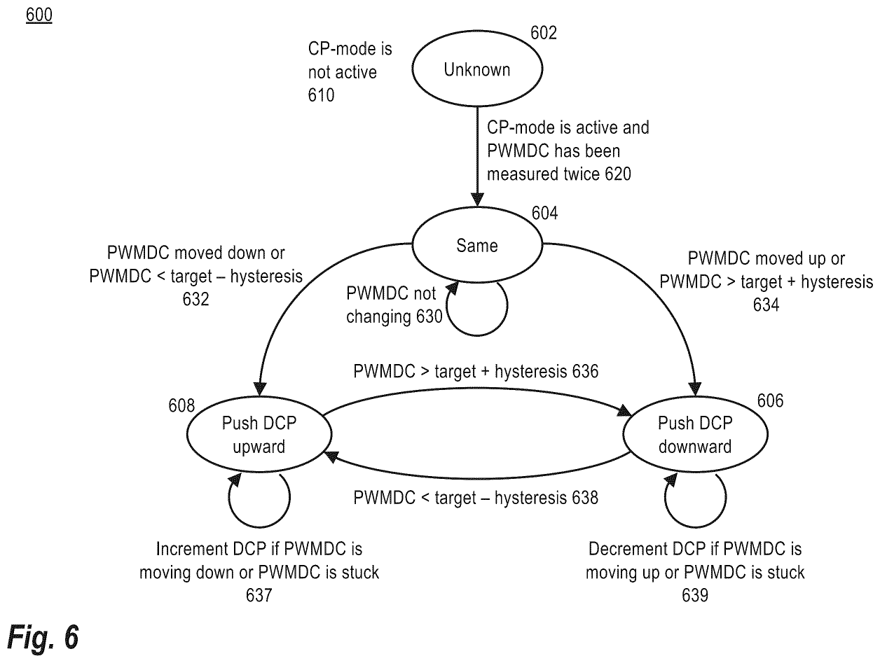

FIG. 6 is a state flow diagram 600 illustrating example aspects of selecting a DCP code for the DCP 302/402 to control the resistance of the feedback resistance divider (or digitally selecting a V_{REF} 301/401 to control the output of transconductance amplifier Gm 303/403) and achieve a desired target COMP voltage. At state 602, the “charge pump” mode may not be active (see 610), and thus no control of the DCP codes may be performed. Once “charge pump” mode has been activated, the duty cycle resulting from pulse width modulation (PWM DC) may be measured (e.g., twice, to detect movement of the PWM DC) (see 620). The regulated PWM DC may be measured by over-sampling a PWM signal, with options for averaging across 1, 2, 4, 8, or N PWM cycles, where N is an integer (odd or even). For example, the PWM signal may be advantageously averaged across 2 ^{k} cycles in an FPGA implementation by using a right-shift operation to perform the division operation for averaging.

Then, the controller 105's state may transition to state 604 in which the PWM DC is not changing (see 630). The controller 105 may determine whether the PWM DC should be moved down or up to achieve the desired target COMP voltage and V_{LX} signal duty cycle (e.g., 50%). If the PWM DC has moved down, or the PWM DC is less than a target PWM DC (accounting for any hysteresis in the measurement) (see 632), the controller 105's state may transition to state 608, in which the controller 105 increments the DCP code to increase the PWM DC. The controller 105 may also increment the DCP code if the PWM DC is moving down or is stuck below the target PWM DC (see 637). If the PWM DC has moved up, or the PWM DC is greater than a target PWM DC (accounting for any hysteresis in the measurement) (see 634), the controller 105's state may transition to state 606, in which the controller 105 decrements the DCP code to decrease the PWM DC. The controller 105 may also decrement the DCP code if the PWM DC is moving up or is stuck above the target PWM DC (see 639). The controller 105's state may also transition between states 606 and 608 depending on whether the PWM DC is greater than a target PWM DC (accounting for any hysteresis in the measurement) (see 636), or whether the PWM DC is less than a target PWM DC (accounting for any hysteresis in the measurement) (see 638). Once near the desired target COMP, the controller 105's state may toggle between states 606 and 608 as the controller 105 toggles between adjacent DCP codes to maintain the desired target COMP voltage and V_{LX} signal duty cycle (e.g., 50%).

The embodiments may further be described using the following clauses:
1. A control circuit for controlling a pulse-width modulation (PWM) signal for a multi-level converter, wherein the multi-level converter is capable of operations in a charge pump mode by open loop control and a regulation mode by closed-loop control, the control circuit comprising:
   a compensation signal generation circuit configured to generate a compensation signal; and
   a PWM circuit configured to generate a PWM signal with a target duty cycle based on the compensation signal when the multi-level converter operates in the charge pump mode, the PWM signal with the target duty cycle being used for controlling the multi-level converter in a mode change from the charge pump mode to the regulation mode.
2. The control circuit of clause 1, wherein the compensation signal generation circuit comprises:
   a resistive divider circuit configured to receive an output voltage signal from the multi-level converter, receive a digital code, and divide the output voltage signal to obtain a feedback signal with a voltage based on the digital code; and
   a transconductance amplifier having a first input to receive a signal of a reference voltage and a second input to receive the feedback signal from the resistive divider circuit, and configured to generate the compensation signal based on the feedback signal.
3. The control circuit of clause 1, wherein the compensation signal generation circuit comprises:
a resistive divider circuit configured to receive an output voltage signal from the multi-level converter, and divide the output voltage signal to obtain a feedback signal; and
a transconductance amplifier having a first input to receive a signal of an adjustable voltage and a second input to receive the feedback signal, and configured to generate the compensation signal based on the signal of the adjustable voltage.
4. The control circuit of clause 1, wherein the compensation signal generation circuit comprises an analog circuit to provide the compensation signal at a target voltage, the analog circuit having a first input to receive a signal of the target voltage and a second input to receive a loopback signal from an output of the analog circuit, and being configured to generate the compensation signal based on the signal of the target voltage.
5. The control circuit of any one of clauses 1-4, wherein when the multi-level converter operates in a voltage regulating mode, the PWM circuit is configured to generate the PWM signal with the target duty cycle based on a sawtooth signal and the compensation signal.
6. The control circuit of any one of clauses 1-4, wherein when the multi-level converter operates in a current regulating mode, the PWM circuit is configured to generate the PWM signal with the target duty cycle based on a triangle signal and the compensation signal by slope compensation.
7. The control circuit of any one of clauses 1-6, further comprising:
   a voltage level control circuit configured to:
   receive the PWM signal from the PWM circuit; and
   generate, based on the PWM signal, a plurality of level control signals for controlling the multi-level converter to:
   operate in the charge pump mode by open loop control and supply an output voltage signal of one of a plurality of voltage levels, or
   operate in the regulation mode by closed-loop control and supply the output voltage signal of a variable voltage.
8. The control circuit of clause 7, wherein:
   the multi-level converter operates with a duty cycle of 50% in the charge pump mode to supply the output voltage signal; or
   the multi-level converter operates with an adjustable duty cycle in the regulation mode to supply the output voltage signal.
9. The control circuit of clause 7, wherein the voltage level control circuit is configured to generate the plurality of level control signals with a fixed duty cycle, for controlling the multi-level converter in the charge pump mode to supply the output voltage signal of one of the plurality of voltage levels, a first of the level control signals having a phase shift from a second of the level control signals.
10. The control circuit of clause 7, wherein the voltage level control circuit is configured to generate the plurality of level control signals for controlling the multi-level converter in the regulation mode to supply the output voltage signal with the variable voltage between a first of the plurality of voltage levels minus a voltage boundary zone window value and the first voltage level plus the voltage boundary zone window value.
11. The control circuit of clause 10, wherein the multi-level converter operates with a duty cycle between 50% minus a duty cycle boundary zone window value and 50% plus the duty cycle boundary zone window value.
12. A method for controlling a multi-level converter, the method comprising:
   determining a duty cycle of a pulse-width modulation (PWM) signal, the PWM signal being configured for controlling the multi-level converter;
   determining at least one of: whether the duty cycle of the PWM signal is moved down, moved up, or not changing; or whether the duty cycle of the PWM signal is less than a target duty cycle or greater than the target duty cycle;
   responsive to a determination that the duty cycle of the PWM signal is moved down or a determination that the duty cycle of the PWM signal is less than the target duty cycle, increasing a parameter to increase the duty cycle of the PWM signal; and
   responsive to a determination that the duty cycle of the PWM signal is moved up or a determination that the duty cycle of the PWM signal is greater than the target duty cycle, decreasing the parameter to decrease the duty cycle of the PWM signal.
13. The method of clause 12, wherein determining the duty cycle of the PWM signal comprises:
   measuring the PWM signal to obtain a first duty cycle at a first time and a second duty cycle at a second time, the first and second times being times at which the multi-level converter is in a charge pump mode; and
   determining the duty cycle of the PWM signal based on the first duty cycle and the second duty cycle.
14. The method of clause 12 or 13, wherein:
   determining whether the duty cycle of the PWM signal is less than the target duty cycle comprises determining whether the duty cycle of the PWM signal is less than the target duty cycle minus a hysteresis value; and
   determining whether the duty cycle of the PWM signal is greater than the target duty cycle comprises determining whether the duty cycle of the PWM signal is greater than the target duty cycle plus the hysteresis value.
15. The method of clause 12, wherein the duty cycle of the PWM signal is a first the duty cycle of the PWM signal, the method further comprising:
   after determining at least one of whether a first duty cycle of the PWM signal is moved down, moved up, or not changing, or whether the first duty cycle of the PWM signal is less than a target duty cycle or greater than the target duty cycle:
   determining a second duty cycle of the PWM signal;
   determining at least one of: whether the second duty cycle of the PWM signal is moved down, moved up, or stuck, or whether the second duty cycle of the PWM signal is less than the target duty cycle or greater than the target duty cycle;
   responsive to a determination that the second duty cycle of the PWM signal is moved down or a determination that the second duty cycle of the PWM signal is less than the target duty cycle, increasing the parameter to increase the duty cycle of the PWM signal; and
   responsive to a determination that the second duty cycle of the PWM signal is moved up or a determination that the second duty cycle of the PWM signal is greater than the target duty cycle, decreasing the parameter to decrease the duty cycle of the PWM signal.
16. The method of any one of clauses 12-15, wherein the target duty cycle is 50%.
17. A system for reducing transients during changes of power conversion modes, the system comprising:
   a multi-level converter configured to operate in a charge pump mode or a regulation mode, to provide an output voltage signal; and
   a control circuit configured to:
   control the multi-level converter to operate with a duty cycle of 50% in the charge pump mode by open-loop control, or to operate with a variable duty cycle in the regulation mode by closed-loop control; and
   generate a pulse-width modulation (PWM) signal with a target duty cycle when the multi-level converter operates in the charge pump mode, the PWM signal with the target duty cycle being used for controlling the multi-level converter in a mode change from the charge pump mode to the regulation mode.
18. The system of clause 17, wherein the control circuit comprises:
   a compensation signal generation circuit configured to generate a compensation signal for generating the PWM signal; and
   a PWM circuit configured to generate the PWM signal with the target duty cycle based on the compensation signal.
19. The system of clause 18, wherein the compensation signal generation circuit comprises:
   a resistive divider circuit configured to receive the output voltage signal from the multi-level converter, receive a digital code, and divide the output voltage signal to obtain a feedback signal with a voltage based on the digital code; and
   a transconductance amplifier having a first input to receive a signal of a reference voltage and a second input to receive the feedback signal from the resistive divider circuit, and configured to generate the compensation signal based on the feedback signal.
20. The system of clause 18, wherein the compensation signal generation circuit comprises:
   a resistive divider circuit configured to receive the output voltage signal from the multi-level converter, and divide the output voltage signal to obtain a feedback signal; and
   a transconductance amplifier having a first input to receive a signal of an adjustable voltage and a second input to receive the feedback signal and configured to generate the compensation signal based on the signal of the adjustable voltage.
21. A system for reducing transients during mode changes in a switched capacitor circuit multi-level converter, comprising:
   a switched capacitor-based converter;
   a control circuit to control the switched capacitor-based converter, the control circuit capable of open-loop and closed-loop control of the switched capacitor-based converter;
   wherein the control circuit during open-loop control is configured to control a duty cycle of a switch state transition at about 50%, using feedback from an output of the switched capacitor-based converter.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, the term “coupled” may also be termed as “electrically coupled,” and the term “connected” may be termed as “electrically connected.” “Coupled” and “connected” may also be used to indicate that two or more elements cooperate or interact with each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A control circuit for controlling a pulse-width modulation (PWM) signal for a multi-level converter, wherein the multi-level converter is capable of operations in a charge pump mode by open loop control and a regulation mode by closed-loop control, the control circuit comprising:
a compensation signal generation circuit configured to generate a compensation signal; and
a PWM circuit configured to generate a PWM signal with a target duty cycle based on the compensation signal when the multi-level converter operates in the charge pump mode, the PWM signal with the target duty cycle being used to control the multi-level converter in a mode change from the charge pump mode to the regulation mode.

2. The control circuit of claim 1, wherein the compensation signal generation circuit comprises:
a resistive divider circuit configured to:
receive an output voltage signal from the multi-level converter,
receive a digital code, and
divide the output voltage signal to obtain a feedback signal with a voltage based on the digital code; and
a transconductance amplifier
having a first input to receive a signal of a reference voltage and a second input to receive the feedback signal from the resistive divider circuit, and
configured to generate the compensation signal based on the feedback signal.

3. The control circuit of claim 1, wherein the compensation signal generation circuit comprises:
a resistive divider circuit configured to:
receive an output voltage signal from the multi-level converter, and
divide the output voltage signal to obtain a feedback signal; and
a transconductance amplifier
having a first input to receive a signal of an adjustable voltage and a second input to receive the feedback signal, and
configured to generate the compensation signal based on the signal of the adjustable voltage.

4. The control circuit of claim 1, wherein the compensation signal generation circuit comprises:
an analog circuit to provide the compensation signal at a target voltage, the analog circuit having a first input to receive a signal of the target voltage and a second input to receive a loopback signal from an output of the analog circuit, and
being configured to generate the compensation signal based on the signal of the target voltage.

5. The control circuit of claim 1, wherein when the multi-level converter operates in a voltage regulating mode, the PWM circuit is configured to generate the PWM signal with the target duty cycle based on a sawtooth signal and the compensation signal.

6. The control circuit of claim 1, wherein when the multi-level converter operates in a current regulating mode, the PWM circuit is configured to generate the PWM signal with the target duty cycle based on a triangle signal and the compensation signal by slope compensation.

7. The control circuit of claim 1, further comprising:
a voltage level control circuit configured to:
receive the PWM signal from the PWM circuit; and
generate, based on the PWM signal, a plurality of level control signals to control the multi-level converter to:
operate in the charge pump mode by open loop control and supply an output voltage signal of one of a plurality of voltage levels, or
operate in the regulation mode by closed-loop control and supply the output voltage signal of a variable voltage.

8. The control circuit of claim 7, wherein:
the multi-level converter is configured to operate with a duty cycle of 50% in the charge pump mode to supply the output voltage signal; or
the multi-level converter is configured to operate with an adjustable duty cycle in the regulation mode to supply the output voltage signal.

9. The control circuit of claim 7, wherein the voltage level control circuit is configured to generate the plurality of level control signals with a fixed duty cycle to control the multi-level converter in the charge pump mode to supply the output voltage signal of one of the plurality of voltage levels, a first of the level control signals having a phase shift from a second of the level control signals.

10. The control circuit of claim 7, wherein the voltage level control circuit is configured to generate the plurality of level control signals to control the multi-level converter in the regulation mode to supply the output voltage signal with the variable voltage between
a first voltage level of the plurality of voltage levels minus a voltage boundary zone window value and
the first voltage level plus the voltage boundary zone window value.

11. The control circuit of claim 10, wherein the multi-level converter is configured to operate with a duty cycle between 50% minus a duty cycle boundary zone window value and 50% plus the duty cycle boundary zone window value.

12. A method for controlling a multi-level converter, the method comprising:
determining a duty cycle of a pulse-width modulation (PWM) signal to control the multi-level converter;
determining at least one of:
whether the duty cycle of the PWM signal is moved down, moved up, or not changing; or
whether the duty cycle of the PWM signal is less than a target duty cycle or greater than the target duty cycle;
responsive to a determination that the duty cycle of the PWM signal is moved down or a determination that the duty cycle of the PWM signal is less than the target duty cycle, increasing a parameter to increase the duty cycle of the PWM signal; and
responsive to a determination that the duty cycle of the PWM signal is moved up or a determination that the duty cycle of the PWM signal is greater than the target duty cycle, decreasing the parameter to decrease the duty cycle of the PWM signal.

13. The method of claim 12, wherein determining the duty cycle of the PWM signal comprises:
measuring the PWM signal to obtain a first duty cycle at a first time and a second duty cycle at a second time, the first and second times being times at which the multi-level converter is in a charge pump mode; and
determining the duty cycle of the PWM signal based on the first duty cycle and the second duty cycle.

14. The method of claim 12, wherein:
determining whether the duty cycle of the PWM signal is less than the target duty cycle comprises determining whether the duty cycle of the PWM signal is less than the target duty cycle minus a hysteresis value; and
determining whether the duty cycle of the PWM signal is greater than the target duty cycle comprises determining whether the duty cycle of the PWM signal is greater than the target duty cycle plus the hysteresis value.

15. The method of claim 12, wherein the duty cycle of the PWM signal is a first duty cycle of the PWM signal, the method further comprising:
after determining at least one of whether the first duty cycle of the PWM signal is moved down, moved up, or not changing, or whether the first duty cycle of the PWM signal is less than the target duty cycle or greater than the target duty cycle:
determining a second duty cycle of the PWM signal;
determining at least one of:
whether the second duty cycle of the PWM signal is moved down, moved up, or stuck, or
whether the second duty cycle of the PWM signal is less than the target duty cycle or greater than the target duty cycle;
responsive to a determination that the second duty cycle of the PWM signal is moved down or a determination that the second duty cycle of the PWM signal is less than the target duty cycle, increasing the parameter to increase the duty cycle of the PWM signal; and
responsive to a determination that the second duty cycle of the PWM signal is moved up or a determination that the second duty cycle of the PWM signal is greater than the target duty cycle, decreasing the parameter to decrease the duty cycle of the PWM signal.

16. The method of claim 12, wherein the target duty cycle is 50%.

17. A system for reducing transients during changes of power conversion modes, the system comprising:
a multi-level converter configured to operate in a charge pump mode or a regulation mode to provide an output voltage signal; and
a control circuit configured to:
control the multi-level converter to operate with a duty cycle of 50% in the charge pump mode by open-loop control, or to operate with a variable duty cycle in the regulation mode by closed-loop control; and
generate a pulse-width modulation (PWM) signal with a target duty cycle when the multi-level converter operates in the charge pump mode, the PWM signal with the target duty cycle being used to control the multi-level converter in a mode change from the charge pump mode to the regulation mode.

18. The system of claim 17, wherein the control circuit comprises:
a compensation signal generation circuit configured to generate a compensation signal; and
a PWM circuit configured to generate the PWM signal with the target duty cycle based on the compensation signal.

19. The system of claim 18, wherein the compensation signal generation circuit comprises:
a resistive divider circuit configured to:
receive the output voltage signal from the multi-level converter,
receive a digital code, and
divide the output voltage signal to obtain a feedback signal with a voltage based on the digital code; and
a transconductance amplifier
having a first input to receive a signal of a reference voltage and a second input to receive the feedback signal from the resistive divider circuit, and
configured to generate the compensation signal based on the feedback signal.

20. The system of claim 18, wherein the compensation signal generation circuit comprises:
a resistive divider circuit configured to:
receive the output voltage signal from the multi-level converter, and divide the output voltage signal to obtain a feedback signal; and
a transconductance amplifier having a first input to receive a signal of an adjustable voltage and a second input to receive the feedback signal, and configured to generate the compensation signal based on the signal of the adjustable voltage.
